(19) United States
(12) Patent Application Publication
(10) Pub. No.: US 2007/0099097 A1
(43) Pub. Date: May 3, 2007

(54) Multi-purpose measurement marks for semiconductor devices, and methods, systems and computer program products for using same

(75) Inventor: Dae Kwon Kang, Fishkill, NY (US)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/265,925

(22) Filed: Nov. 3, 2005

(51) Int. Cl. G03F 1/00; G03C 5/00; H01L 21/76; G03F 9/00; H01L 23/544

(52) U.S. Cl. 430/22; 257/797; 438/975; 438/401; 430/30; 430/5

(57) ABSTRACT

A mark for use in measuring characteristics of a layer of the semiconductor device includes multiple staggered L-shaped patterns including adjacent vertices, and legs that include line segments having variable spacing between them. Related methods, systems and computer program products for using the mark to calibrate semiconductor devices also are described.

### FIELD OF THE INVENTION

This invention relates to fabricating semiconductor devices, and more specifically to measurement marks for semiconductor devices, and methods, systems and computer program products for using same.

### BACKGROUND OF THE INVENTION

Integrated circuit semiconductor devices are widely used for consumer, commercial and other applications. As is well known to those having skill in the art, integrated circuit semiconductor devices are fabricated by forming a plurality of patterned semiconductor, insulator and/or conductive layers in and/or on a substrate. The layers may be patterned by imaging through a patterned mask and/or reticle, and/or by direct writing of an image using, for example, electron beams. Often, multiple integrated circuit devices are fabricated in a single semiconductor wafer, which is then diced along scribe lines to define individual integrated circuits.

As the integration density of integrated circuits continues to increase, larger numbers of layers may be formed on a substrate, and/or the line widths of individual layers may decrease. Unfortunately, as the number of layers increase and/or the line widths decrease, it may be exceedingly difficult to align the plurality of layers to one another, and to accurately replicate the mask, reticle and/or direct writing pattern in a given layer.

In order to measure the alignment among layers and the accuracy of the replication of an image in layer, various measurement patterns are also conventionally formed in the various layers of a semiconductor device. These patterns will be referred to herein as “measurement marks” or simply “marks”. These marks are separate from the active circuitry of the semiconductor device. In order to conserve the active real estate of the semiconductor device, these marks are often formed in the scribe lines of a semiconductor wafer.

These marks may be configured to allow measurement of various conditions. For example, alignment marks may be used to measure an amount of misalignment between an overlying layer and an underlying layer of the semiconductor device. Corner rounding marks also may be used to measure the rounding of a sharp corner of a mask, reticle and/or direct write image data when this corner is fabricated in a layer of a semiconductor device. Finally, line end shortening marks are used to measure changes in distances between ends of adjacent lines of a mask, reticle and/or direct write data, when the adjacent lines are fabricated in a layer of a semiconductor device. These various marks are well known to those having skill in the art. For example, alignment marks are described in U.S. Pat. No. 6,486,954 to Mieher et al., entitled Overlay Alignment Measurement Mark. Moreover, line end shortening and corner rounding are described in U.S. Pat. No. 6,944,844 to Liu, entitled System and Method to Determine Impact of Line End Shortening. Finally, corner rounding is described, for example, in U.S. Pat. No. 6,925,202 to Karklin et al., entitled System and Method of Providing Mask Quality Control. Unfortunately, as the integration density of integrated circuits continues to increase, it may be difficult to fabricate the requisite marks in the scribe lines and/or in the integrated circuit devices themselves.

### SUMMARY OF THE INVENTION

An overlying layer of a semiconductor device may be calibrated relative to an underlying layer of the semiconductor device by forming a solid cross on the underlying layer of the semiconductor device, to define four quadrants and a center. A plurality of first through fourth staggered L-shaped patterns are formed on the overlying layer of the semiconductor device, each of the first through fourth staggered L-shaped patterns including adjacent vertices, and legs that comprise line segments including variable spacing therebetween. The first through fourth staggered L-shaped patterns are oriented such that adjacent vertices of the first through fourth staggered L-shaped patterns are adjacent the center of the solid cross and a respective one of the first through fourth staggered L-shaped patterns occupies a respective one of the four quadrants.

Misalignment between the overlying layer and the underlying layer, corner rounding in the overlying layer and line end shortening in the overlying layer are then measured using the solid cross and the plurality of first through fourth staggered L-shaped patterns. In particular, in some embodiments, misalignment may be measured by measuring misalignment between the solid cross and the first through fourth staggered L-shaped patterns. Corner rounding may be measured by measuring the vertices of the staggered L-shaped patterns relative to one another, and/or relative to the center of the solid cross. Finally, line end shortening may be measured by measuring the variable spacing in the legs of the L-shaped patterns. By combining alignment, corner rounding and line end shortening measurements into a single pair of marks, valuable real estate in an integrated circuit and/or in wafer scribe lines may be conserved. Analogous systems for calibrating an overlying layer of a semiconductor device relative to an underlying layer of the semiconductor device also may be provided according to other embodiments of the present invention. Moreover, analogous computer program products for measuring misalignment also may be provided according to still other embodiments of the present invention.

In some embodiments of the invention, a plurality spaced apart solid crosses may be formed on the underlying layer of the semiconductor device, a respective one of which defines four quadrants and a center. A plurality of first through fourth staggered L-shaped patterns may then be formed on a respective one of the plurality of overlying layers of the semiconductor device, each including adjacent vertices, and legs that comprise line segments including variable spacing therebetween, oriented such that the adjacent vertices of a respective overlying layer are adjacent a respective center of a respective solid cross and a respective one of the first through staggered L-shaped patterns occupies a respective one of the four quadrants of a respective solid cross. In other embodiments, a solid cross is also formed on the overlying layer of the semiconductor device that is spaced apart from the plurality of first through fourth staggered L-shaped patterns in the overlying layer.

A basic building block or unit cell of a mark for use in measuring a plurality of characteristics of layer of the semiconductor device, according to some embodiments of the present invention, includes a plurality of first staggered L-shaped patterns including adjacent vertices, and legs that comprise line segments including variable spacing therebetween. In some embodiments, a plurality of second staggered L-shaped patterns including adjacent vertices, and legs that comprise line segments including variable spacing therebetween are also provided. The plurality of first and second staggered L-shaped patterns are spaced apart from one another and oriented such that the vertices and first legs of the plurality of first and second staggered L-shaped patterns are adjacent one another, and second legs of the plurality of first and second staggered L-shaped patterns extend in opposite directions. In other embodiments, a plurality of first through fourth staggered L-shaped patterns are provided, each including adjacent vertices and legs that comprise line segments including variable spacing therebetween. The plurality of first through fourth staggered L-shaped patterns are spaced apart from one another and oriented, such that the vertices of the first through fourth staggered L-shaped patterns are adjacent one another, and a respective one of the first through fourth staggered L-shaped patterns occupies a respective quadrant around the vertices that are adjacent one another. The L-shaped patterns may be combined with a solid L-shaped pattern that is included in a second layer of the semiconductor device.

Marks according to any of the above embodiments of the present invention may be contained in a semiconductor wafer, in a scribe line of a semiconductor wafer, in a mask or reticle for a semiconductor wafer and/or in patterning data for a semiconductor wafer.

### BRIEF DESCRIPTION OF THE DRAWINGS

FIG. 1 is a top plan view of a mark for use in measuring characteristics of a layer of a semiconductor device, according to various embodiments of the present invention.

FIGS. 2-4 are exploded views of portions of a mark of FIG. 1, illustrating the measurement of misalignment, line end shortening and corner rounding, respectively, according to various embodiments of the present invention.

FIGS. 5 and 6 schematically illustrate layers of a semiconductor device including marks, according to various embodiments of the present invention.

FIG. 7 is a flowchart of operations that may be performed to calibrate an overlying layer of a semiconductor device relative to an underlying layer of the semiconductor device, according to various embodiments of the present invention.

FIG. 8 is a block diagram of a system for measuring misalignment, corner rounding and line end shortening from a pair of overlapping marks, according to various embodiments of the present invention.

### DETAILED DESCRIPTION

The invention will be described more fully hereinafter with reference to the accompanying drawings, in which example embodiments of the invention are shown. This invention may, however, be embodied in many different forms and should not be construed as limited to the example embodiments set forth herein. Rather, the disclosed embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element or layer is referred to as being “on”, “connected to” and/or “coupled to” another element or layer, it can be directly on, connected or coupled to the other element or layer or intervening elements or layers may be present. In contrast, when an element is referred to as being “directly on,” “directly connected to” and/or “directly coupled to” another element or layer, there are no intervening elements or layers present. As used herein, the term “and/or” may include any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms may be used to distinguish one element, component, region, layer and/or section from another region, layer and/or section. For example, a first element, component, region, layer and/or section discussed below could be termed a second element, component, region, layer and/or section without departing from the teachings of the present invention.

Spatially relative terms, such as “beneath”, “below”, “lower”, “above”, “upper” and the like, may be used herein for ease of description to describe an element and/or a feature's relationship to another element(s) and/or feature(s) as illustrated in the figures. It will be understood that the spatially relative terms are intended to encompass different orientations of the device in use or operation in addition to the orientation depicted in the figures. For example, if the device in the figures is turned over, elements described as “below” and/or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular terms “a”, “an” and “the” are intended to include the plural forms as well, unless the context clearly indicates otherwise. It will be further understood that the terms “comprises,” “comprising,” “includes” and/or “including” when used in this specification, specify the presence of stated features, integers, steps, operations, elements, and/or components, but do not preclude the presence or addition of one or more other features, integers, steps, operations, elements, components, and/or groups thereof.

Example embodiments of the invention are described herein with reference to top plan views that are schematic illustrations of idealized embodiments (and intermediate structures) of the invention. As such, variations from the shapes of the illustrations as a result, for example, of manufacturing techniques and/or tolerances, may be expected. Thus, the disclosed example embodiments of the invention should not be construed as limited to the particular shapes of regions illustrated herein unless expressly so defined herein, but are to include deviations in shapes that result, for example, from manufacturing. For example, a corner region illustrated as sharp will, typically, have rounded or curved features. Thus, the regions illustrated in the figures are schematic in nature and their shapes are not intended to illustrate the actual shape of a region of a device and are not intended to limit the scope of the invention, unless expressly so defined herein.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The present invention is described in part below with reference to block diagrams and flowcharts of methods, systems and computer program products according to embodiments of the invention. It will be understood that a block of the block diagrams or flowcharts, and combinations of blocks in the block diagrams or flowcharts, may be implemented at least in part by computer program instructions. These computer program instructions may be provided to one or more enterprise, application, personal, pervasive and/or embedded computer systems, such that the instructions, which execute via the computer system(s) create means, modules, devices or methods for implementing the functions/acts specified in the block diagram block or blocks. Combinations of general purpose computer systems and/or special purpose hardware also may be used in other embodiments.

These computer program instructions may also be stored in memory of the computer system(s) that can direct the computer system(s) to function in a particular manner, such that the instructions stored in the memory produce an article of manufacture including computer-readable program code which implements the functions/acts specified in block or blocks. The computer program instructions may also be loaded into the computer system(s) to cause a series of operational steps to be performed by the computer system(s) to produce a computer implemented process such that the instructions which execute on the processor provide steps for implementing the functions/acts specified in the block or blocks. Accordingly, a given block or blocks of the block diagrams and/or flowcharts provides support for methods, computer program products and/or systems (structural and/or means-plus-function).

It should also be noted that in some alternate implementations, the functions/acts noted in the flowcharts may occur out of the order noted in the flowcharts. For example, two blocks shown in succession may in fact be executed substantially concurrently or the blocks may sometimes be executed in the reverse order, depending upon the functionality/acts involved. Finally, the functionality of one or more blocks may be separated and/or combined with that of other blocks.

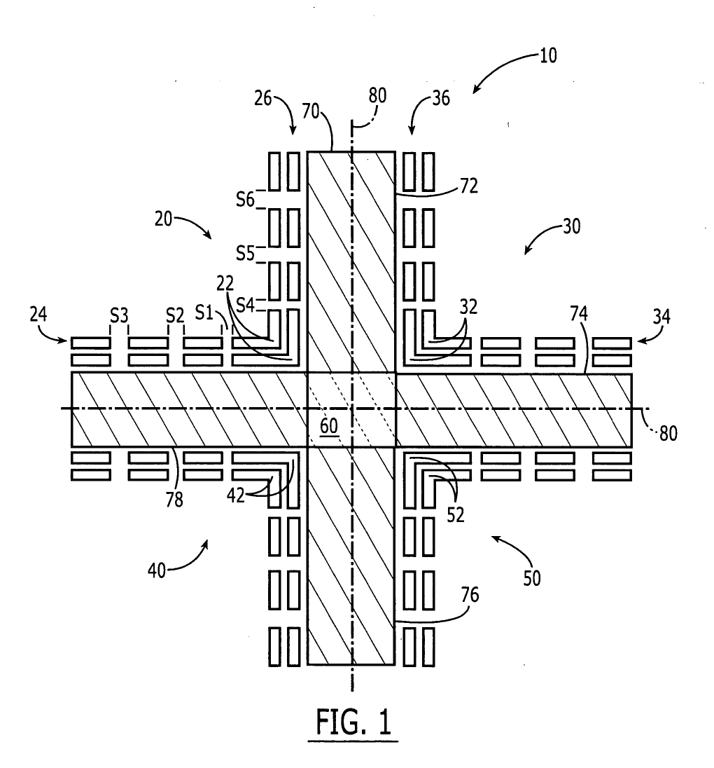

FIG. 1 is a top plan view of marks for use in measuring a plurality of characteristics of a layer of a semiconductor device according to various embodiments of the present invention. As shown in FIG. 1, an exemplary mark 10 includes a plurality, here two, of staggered L-shaped patterns 20 including adjacent vertices 22, and legs 24, 26 that comprise line segments including variable spacing S1-S6 therebetween.

It will be understood by those having skill in the art that the staggered L-shaped patterns 20 are illustrated in FIG. 1 as including two staggered L-shaped patterns, but more than two staggered L-shaped patterns 20 also may be used. Moreover, in FIG. 1, the legs 24 and 26 each include four line segments with three different size spaces therebetween. However, larger or smaller numbers of line segments may be included. Also, as used herein, variable spacing therebetween means that at least two spacings between line segments of a given leg 24, 26 are different from one another. Thus, although the line spacings S1, S2, S3 and S4, S5, S6 of FIG. 1 are illustrated as linearly increasing in a given leg 24, 26 from the vertex 22 to the end, uniform changes in spacing need not be provided. Moreover, the spacings S1, S2, S3 and S4, S5, S6 of the respective legs 24, 26 need not be identical to one another. Finally, the spacings between adjacent staggered L-shaped patterns 20 need not be the same.

Still continuing with the description of FIG. 1, in some embodiments of the present invention, a plurality of staggered L-shaped patterns 20 is a plurality of first staggered L-shaped patterns, and the mark 10 further includes a plurality of second staggered L-shaped patterns 30, which also include adjacent vertices 32 and legs 36, 38 that comprise line segments including a variable spacing therebetween. As shown in FIG. 1, the plurality of first and second staggered L-shaped patterns 20 and 30 are spaced apart from one another and oriented such that the vertices 22, 32 and the first legs 26, 36 of the plurality of first and second staggered L-shaped patterns 20 and 30, respectively, are adjacent one another, and the second legs 24, 34 of the plurality of first and second staggered L-shaped patterns 20, 30 extend in opposite directions, shown as to the left and to the right in FIG. 1.

Moreover, in still other embodiments of the present invention, the mark 10 includes a plurality of first 20, second 30, third 40 and fourth 50 staggered L-shaped patterns, each including adjacent vertices 22, 32, 42, 52, respectively, and legs that comprise line segments including variable spacing therebetween. The plurality of first through fourth staggered L-shaped patterns are spaced apart from one another, and oriented such that the vertices 22, 32, 42 and 52 of the first through fourth staggered L-shaped patterns are adjacent one another, and a respective one of the first through fourth staggered L-shaped patterns occupies a respective quadrant around the vertices that are adjacent one another, as shown in FIG. 1. As also shown in FIG. 1, in some embodiments of the present invention, the mark 10 may also include a center portion 60 between the vertices 22, 32, 42 and 52 of the respective plurality of first through fourth staggered L-shaped patterns 20, 30, 40 and 50.

In some embodiments of the present invention, the plurality of staggered L-shaped patterns 20, 30, 40 and/or 50 and, in some embodiments, the center portion 60, are included in a first layer of a semiconductor device, as shown by the unhatched shading of these elements. In some embodiments, the mark further includes a solid cross pattern 70, shown as hatched in FIG. 1. The solid cross-shaped pattern 70 includes a center that is positioned between the vertices 22, 32, 42 and 52 of the first through fourth staggered L-shaped patterns 20, 30, 40 and 50, and includes four legs 72, 74, 76, 78, a respective one of which extends along a respective boundary region among the respective quadrants, shown by the imaginary dashed line 80 of FIG. 1. When only a single staggered L-shaped pattern, such as staggered L-shaped pattern 20, is present, the solid cross 70 may be replaced by a solid L-shaped pattern that is included in the second layer of the semiconductor device, for example, the L-shaped portion of the solid cross 70.

In some embodiments of the present invention, the mark 10 is contained in a semiconductor wafer and, in some embodiments, in a scribe line of a semiconductor wafer. In other embodiments, the mark 10 is contained in a mask or reticle for a semiconductor wafer. In still other embodiments, mark is contained in patterning data for a semiconductor wafer, such as direct write patterning data for a semiconductor wafer.

FIG. 2 is an exploded view of a portion of the mark of FIG. 1, illustrating measuring misalignment between an overlying layer and an underlying layer according to various embodiments of the present invention. As shown in FIG. 2, in an exploded view, the actual edges of the legs 26 and 36 and the cross 70 are not straight when formed in a layer of the semiconductor device, due to various nonlinearities, tolerances and/or well known effects. A scan 200 may be performed across the leg 26, across a portion of the cross 70 and across the leg 36, and the signal from the scan may be processed to measure misalignment between the underlying layer that contains the cross 70 and the overlying layer that contains the mark 10, including the legs 26 and 36. It will be understood by those having skill in the art that FIG. 2 is merely representative, and misalignment may be measured across various portions of the mark 10 and cross 70, and may be performed in various directions at multiple locations and/or using multiple scans 200.

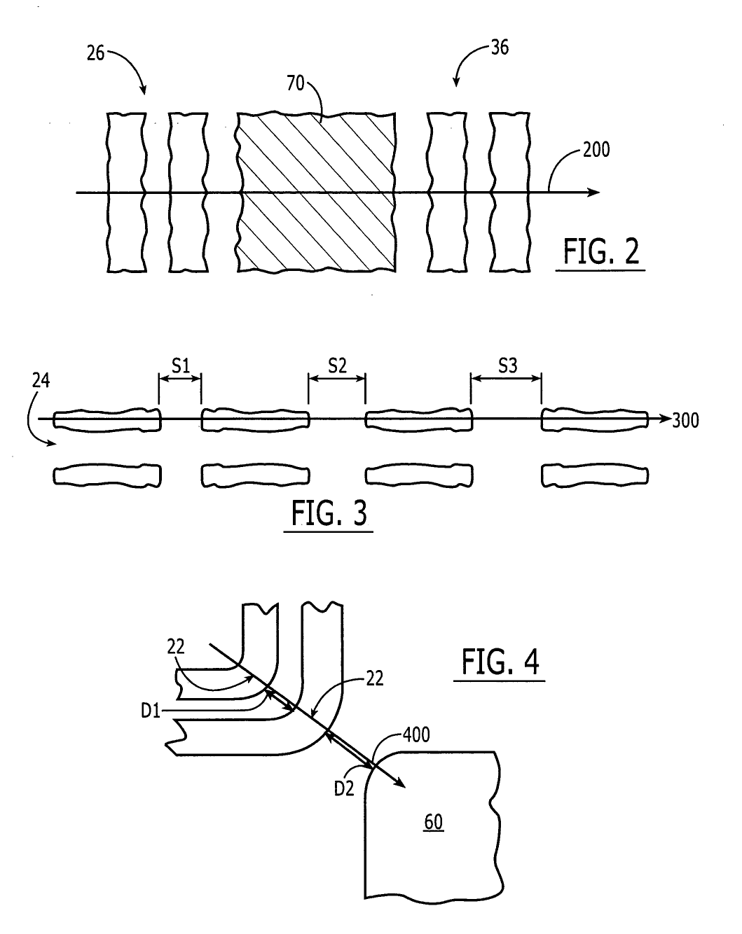

FIG. 3 is an exploded view of another portion of the mark 10 of FIG. 1 illustrating measurement of line end shortening according to various embodiments of the present invention. As shown in FIG. 3, the line segments in the leg 24 may be formed in a semiconductor device with rounded and/or shortened edges and/or various other imperfections, and a scan 300 may be performed to measure the variable distances S1, S2 and S3, to determine line end shortening. It will also be understood by those having skill in the art that FIG. 3 is only representative, and other L-shaped segments 30, 40 and/or 50, and/or other ones of the staggered L-shaped patterns may be used to measure line end shortening according to other embodiments of the present invention.

FIG. 4 is an exploded view of a portion of the mark 10 of FIG. 1, to illustrate measuring of corner rounding according to various embodiments of the present invention. As shown in FIG. 4, the vertices 22 may be rounded rather than sharp when fabricated in a semiconductor device, and/or the corner of the center portion 60 also may be rounded. The distances D1 between adjacent vertices and/or the distance D2 between a vertex 22 and the center portion 60 may be measured by a scan 400, as illustrated in FIG. 4. It will be understood that other quadrants of the pattern also may be used, and that the distances D1 and/or D2 may be measured to detect corner rounding using techniques well known to those having skill in the art. Other techniques also may be used to measure corner rounding using a mark of FIG. 1. Accordingly, as illustrated in FIGS. 1-4, a mark 10 may be used to measure misalignment, line end shortening and/or corner rounding according to various embodiments of the present invention.

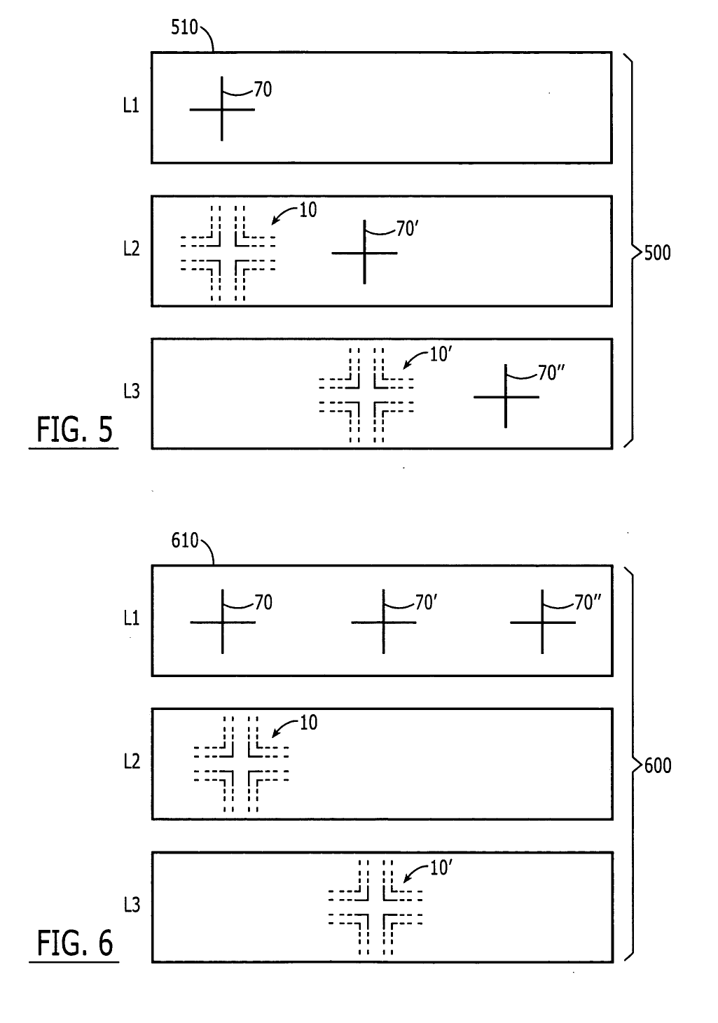

FIG. 5 schematically illustrates how a plurality of layers L1, L2, L3 of a semiconductor device may include marks for measuring characteristics thereof according to various embodiments of the present invention. As shown in FIG. 5, layer L1 underlies layer L2, which itself underlies layer L3, in a semiconductor device 500. Marks according to various embodiments of the present invention may be included in a scribe line 510 in the layers L1, L2 and L3 of a semiconductor wafer and/or in layers of a semiconductor integrated circuit itself. As shown in FIG. 5, in the underlying layer L1, a solid cross 70 is formed. In an overlying layer L2, a plurality of first through fourth staggered L-shaped patterns 70 are formed, each including adjacent vertices, and legs that comprise line segments including variable spacing therebetween and oriented such that the adjacent vertices are adjacent the center of the solid cross 70 and a respective one of the first through fourth staggered L-shaped patterns occupies a respective one of the four quadrants. A second solid cross 70′ also may be formed on the second layer L2 for use in calibrating the third overlying layer L3 using an overlying calibration mark 10′. As also shown, the layer L3 may also contain a third cross 70″ for calibrating additional overlying layers.

In other embodiments, illustrated in FIG. 6, three layers L1, L2, L3 of a semiconductor device 600 may include crosses and alignment marks in a scribe line 610 of a wafer and/or in an integrated circuit portion thereof. As shown in FIG. 6, a first underlying layer L1 may include a plurality of spaced apart crosses 70, 70′, 70″, and each individual overlying layer L2, L3 may include a mark 10, 10′, a respective one of which is used with a respective one of the crosses 70, 70′ for calibration.

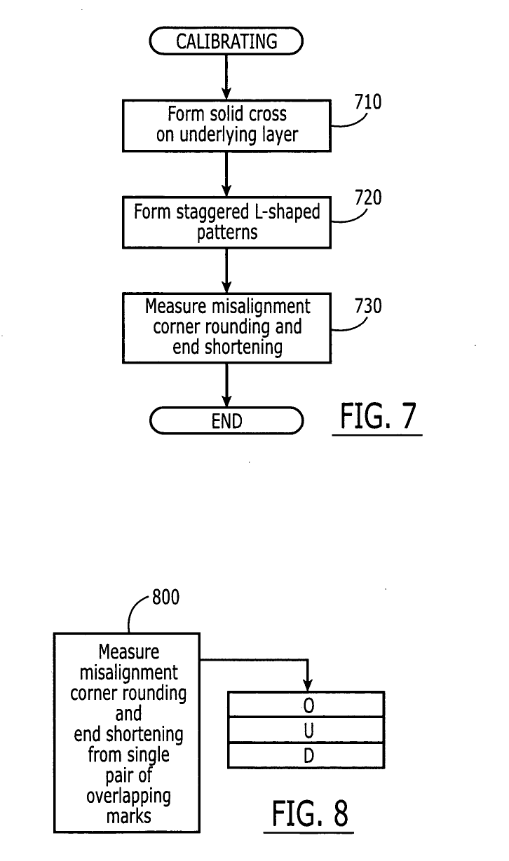

FIG. 7 is a flowchart of operations that may be performed according to various embodiments of the invention, to calibrate an overlying layer of a semiconductor device relative to an underlying layer of the semiconductor device. As shown in Block 710, a solid cross is formed on the underlying layer of the semiconductor device, to define four quadrants and a center. At Block 720, a plurality of first through fourth staggered L-shaped patterns are formed on the overlying layer of the semiconductor device, each including adjacent vertices, and legs that comprise line segments including variable spacing therebetween, and oriented such that the adjacent vertices of the first through fourth staggered L-shaped portions are adjacent the center of the solid cross and a respective one of the first through fourth staggered L-shaped patterns occupies a respective one of the four quadrants. The sequence of Blocks 710 and 720 may be reversed or performed simultaneously. Then at Block 730, misalignment between the overlying layer and the underlying layer, corner rounding in the overlying layer and line end shortening in the overlying layer is measured using the solid cross and the plurality of first through fourth staggered L-shaped patterns. A computer program product may be used, at least in part, to perform the measuring, for example by providing control and/or signal processing algorithms.

It will be understood that in Block 710, a single solid cross may be formed on an underlying layer, as shown in layer L1 of FIG. 5, or a plurality of solid crosses may be formed, as shown in layer L1 of FIG. 6. Similarly, in Block 720, a single staggered L-shaped pattern may be formed, as shown in layer L2 of FIG. 6, or a staggered L-shaped pattern and a spaced apart cross may be formed, as shown in layers L2 and L3 of FIG. 5.

FIG. 8 schematically illustrates systems of calibrating an overlying layer O of a semiconductor device D relative to an underlying layer U of the semiconductor device D, according to various embodiments of the present invention. A calibration system 800 is provided that can measure misalignment, corner rounding and line end shortening from a single pair of overlapping marks, which may include a solid cross and a plurality of first through fourth staggered L-shaped patterns as described herein. The system 800 may include an imaging and/or scanning system, digital signal processing and/or one or more data processors. In particular, a conventional calibration system may be modified to work with marks according to embodiments of the present invention disclosed herein, to allow concurrent measurement of corner rounding, line end shortening and misalignment from a pair of overlapping marks. A computer program product may be used, at least in part, to provide some of the functionality of the system 800.

In the drawings and specification, there have been disclosed embodiments of the invention and, although specific terms are employed, they are used in a generic and descriptive sense only and not for purposes of limitation, the scope of the invention being set forth in the following claims.

What is claimed is:

1. A mark for use in measuring a plurality of characteristics of a layer of a semiconductor device, comprising:
a plurality of staggered L-shaped patterns including adjacent vertices, and legs that comprise line segments including variable spacing therebetween.

2. A mark according to claim 1 wherein the plurality of staggered L-shaped patterns is a plurality of first staggered L-shaped patterns, the mark further comprising:
a plurality of second staggered L-shaped patterns including adjacent vertices, and legs that comprise line segments including variable spacing therebetween, the plurality of first and second staggered L-shaped patterns being spaced apart from one another and oriented such that the vertices and first legs of the plurality of first and second staggered L-shaped patterns are adjacent one another, and second legs of the plurality of first and second staggered L-shaped patterns extend in opposite directions.

3. A mark according to claim 1 wherein the plurality of staggered L-shaped patterns is a plurality of first staggered L-shaped patterns, the mark further comprising:
a plurality of second, third and fourth staggered L-shaped patterns each including adjacent vertices, and legs that comprise line segments including variable spacing therebetween, plurality of first through fourth staggered L-shaped patterns being spaced apart from one another and oriented such that the vertices of the first through fourth staggered L-shaped patterns are adjacent one another, and a respective one of the first through fourth staggered L-shaped patterns occupies a respective quadrant around the vertices that are adjacent one another.

4. A mark according to claim 1 wherein the plurality of staggered L-shaped patterns are included in a first layer of a semiconductor device, the mark further comprising a solid L-shaped pattern that is included in a second layer of the semiconductor device.

5. A mark according to claim 3 wherein the plurality of first through fourth staggered L-shaped patterns are included in a first layer of a semiconductor device, the mark further comprising a solid cross-shaped pattern including a center that is positioned between the vertices of the first through fourth staggered L-shaped patterns that are adjacent one another and including four legs, a respective one of which extends along a respective boundary region among the respective quadrants.

6. A mark according to claim 3 further comprising a center portion between the vertices of the first through fourth staggered L-shaped patterns.

7. A mark according to claim 1 that is contained in a semiconductor wafer.

8. A mark according to claim 1 that is contained in a scribe line of a semiconductor wafer.

9. A mark according to claim 1 that is contained in mask or reticle for patterning a semiconductor wafer.

10. A mark according to claim 1 that is contained in patterning data for a semiconductor wafer.

11. A mark for use in measuring a plurality of characteristics of a layer of a semiconductor device, comprising:
a plurality of patterns substantially as illustrated in FIGS. 1-6.

12. A mark according to claim 11 that is contained in a semiconductor wafer.

13. A mark according to claim 11 that is contained in a scribe line of a semiconductor wafer.

14. A mark according to claim 11 that is contained in mask or reticle for patterning a semiconductor wafer.

15. A mark according to claim 11 that is contained in patterning data for a semiconductor wafer.

16. A method of calibrating an overlying layer of a semiconductor device relative to an underlying layer of the semiconductor device comprising:
forming a solid cross on the underlying layer of the semiconductor device to define four quadrants and a center;
forming a plurality of first through fourth staggered L-shaped patterns on the overlying layer of the semiconductor device, each including adjacent vertices, and legs that comprise line segments including variable spacing therebetween, and oriented such that the adjacent vertices of the first through fourth staggered L-shaped patterns are adjacent the center of the solid cross and a respective one of the first through fourth staggered L-shaped patterns occupies a respective one of the four quadrants; and
measuring misalignment between the overlying layer and the underlying layer, corner rounding in the overlying layer and line end shortening in the overlying layer using the solid cross and the plurality of first through fourth staggered L-shaped patterns.

17. A method according to claim 16 for calibrating a plurality of overlying layers of the semiconductor device:
wherein forming a solid cross comprises forming a plurality of spaced apart solid crosses on the underlying layer of the semiconductor device, a respective one of which defines four quadrants and a center; and
wherein forming a plurality of first through fourth staggered L-shaped patterns comprises forming a plurality of first through fourth staggered L-shaped patterns on a respective one of the plurality of overlying layers of the semiconductor device, each including adjacent vertices, and legs that comprise line segments including variable spacing therebetween, and oriented such that the adjacent vertices of a respective overlying layer are adjacent a respective center of a respective solid cross and a respective one of the first through fourth staggered L-shaped patterns occupies a respective one of the four quadrants of a respective solid cross; and
wherein measuring misalignment comprises measuring misalignment between a respective overlying layer and the underlying layer, corner rounding in a respective overlying layer and line end shortening in a respective overlying layer using the plurality of spaced apart solid crosses and the plurality of first through fourth staggered L-shaped patterns on the respective plurality of overlying layers.

18. A method according to claim 16 wherein the solid cross comprises a first solid cross, the method further comprising:
forming a second solid cross on the overlying layer of the semiconductor device that is spaced apart from the plurality of first through fourth staggered L-shaped patterns.

19. A method according to claim 16 wherein forming a solid cross and forming a plurality of first through fourth staggered L-shaped patterns are performed by imaging a mask or reticle including the solid cross and or the plurality of first through fourth staggered L-shaped patterns.

20. A method according to claim 16 wherein forming a solid cross and forming a plurality of first through fourth staggered L-shaped patterns are performed in a scribe line of a semiconductor wafer that includes the overlying and underlying layers.

21. A system that is configured to perform the method of claim 16.

22. A computer program product comprising a computer-readable storage medium having computer-readable program code embodied in the medium, the computer-readable program code configured to perform measuring misalignment of claim 16.
